(19) United States
(12) Patent Application Publication
(10) Pub. No.: US 2026/0190218 A1
(43) Pub. Date: Jul. 2, 2026

(54) ELECTRONIC DEVICE

(71) Applicant: AUO Corporation, Hsinchu City (TW)

(72) Inventors: Chih-Tsung Lee, Hsinchu City (TW); Chih-Hung Wu, Hsinchu City (TW); Chih-Yu Yu, Hsinchu City (TW); Yen-Huei Lai, Hsinchu City (TW); Wan-Tsang Wang, Hsinchu City (TW)

(73) Assignee: AUO Corporation, Hsinchu City (TW)

(21) Appl. No.: 19/250,086

(22) Filed: Jun. 26, 2025

(30) Foreign Application Priority Data
Dec. 31, 2024 (TW) 113151649

(51) Int. Cl. H05K 1/02

(52) U.S. Cl. CPC H05K 1/0283

(57) ABSTRACT

An electronic device includes a stretchable electronic component layer, a decorative component layer, a transparent hard board layer, and an upper hard board layer. The stretchable electronic component layer has a stretchable zone, a first non-stretchable zone, and a second non-stretchable zone. The stretchable zone is located between the first non-stretchable zone and the second non-stretchable zone. The decorative component layer is disposed on the stretchable electronic component layer. The transparent hard board layer is embedded or buried in the decorative component layer and overlaps with the first non-stretchable zone of the stretchable electronic component layer. The upper hard board layer is embedded or buried in the decorative component layer and overlaps with the second non-stretchable zone of the stretchable electronic component layer.

### CROSS-REFERENCE TO RELATED APPLICATION

This application claims the priority benefit of Taiwan application serial no. 113151649, filed on Dec. 31, 2024. The entirety of the above-mentioned patent application is hereby incorporated by reference herein and made a part of this specification.

### BACKGROUND

### Technical Field

The disclosure relates to an electronic device.

### Description of Related Art

With the rapid development of electronic technology, electronic products are constantly being innovated. In order to enable electronic products to be applied in various different fields, the characteristics of stretchability, lightness, thinness, and unlimited appearance are gradually gaining attention. In other words, electronic products are gradually required to have different appearances according to different applications and application environments, so electronic products need to be stretchable. However, when electronic products are stretched, issues such as separation of multiple internal film layers and irregular warpage may occur due to stress.

### SUMMARY

The disclosure provides an electronic device with good performance.

An electronic device of the disclosure includes a stretchable electronic component layer, a decorative component layer, a transparent hard board layer, and an upper hard board layer. The stretchable electronic component layer has a stretchable zone, a first non-stretchable zone, and a second non-stretchable zone. The stretchable zone is located between the first non-stretchable zone and the second non-stretchable zone. The decorative component layer is disposed on the stretchable electronic component layer. The transparent hard board layer is embedded or buried in the decorative component layer and overlaps with the first non-stretchable zone of the stretchable electronic component layer. The upper hard board layer is embedded or buried in the decorative component layer and overlaps with the second non-stretchable zone of the stretchable electronic component layer.

### BRIEF DESCRIPTION OF THE DRAWINGS

FIG. 1 is a top perspective schematic view of an electronic device according to an embodiment of the disclosure.

FIG. 2 is a cross-sectional schematic view of an electronic device according to an embodiment of the disclosure.

FIG. 3 is a top schematic view of a first non-stretchable zone of a stretchable electronic component layer according to an embodiment of the disclosure.

FIG. 4 is a top schematic view of a low stretchable zone of a stretchable electronic component layer according to an embodiment of the disclosure.

FIG. 5 is a top schematic view of a high stretchable zone of a stretchable electronic component layer according to an embodiment of the disclosure.

FIG. 6 is a cross-sectional schematic view of an electronic device according to an embodiment of the disclosure.

FIG. 7A to FIG. 7F are cross-sectional schematic views of a manufacturing process of an electronic device according to another embodiment of the disclosure.

FIG. 8 shows an application scenario of an electronic device according to yet another embodiment of the disclosure.

FIG. 9 is a top perspective schematic view of an electronic device according to yet another embodiment of the disclosure.

FIG. 10 is a cross-sectional schematic view of an electronic device according to yet another embodiment of the disclosure.

FIG. 11 shows an application scenario of an electronic device according to still another embodiment of the disclosure.

FIG. 12 is a side schematic view of an electronic device according to still another embodiment of the disclosure.

FIG. 13 is a cross-sectional schematic view of an electronic device according to yet another embodiment of the disclosure.

FIG. 14 is a cross-sectional schematic view of an electronic device according to an embodiment of the disclosure.

FIG. 15 is a top perspective schematic view of an electronic device according to another embodiment of the disclosure.

FIG. 16A to FIG. 16F are cross-sectional schematic views of a manufacturing process of an electronic device according to yet another embodiment of the disclosure.

FIG. 17A to FIG. 17F are cross-sectional schematic views of a manufacturing process of an electronic device according to still another embodiment of the disclosure.

FIG. 18A to FIG. 18F are cross-sectional schematic views of a manufacturing process of an electronic device according to an embodiment of the disclosure.

### DESCRIPTION OF THE EMBODIMENTS

Reference will now be made in detail to the exemplary embodiments of the disclosure, and examples of the exemplary embodiments are illustrated in the drawings. Wherever possible, the same reference numerals are used in the drawings and the description to represent the same or similar parts.

It should be understood that when an element such as a layer, a film, a region, or a substrate is referred to as being “on” another element or “connected to” another element, the element may be directly on the another element or connected to the another element, or there may be an intermediate element. In contrast, when an element is referred to as being “directly on” another element or “directly connected to” another element, there is no intermediate element. As used herein, “connection” may refer to physical and/or electrical connection. Furthermore, “electrical connection” or “coupling” may be that there is another element between two elements.

As used herein, “about”, “approximately”, or “substantially” includes the stated value and an average value within an acceptable deviation range of the particular value as determined by persons skilled in the art, while taking into account the measurement in discussion and a particular amount of error (that is, the limitation of a measurement system) associated with the measurement. For example, “about” may represent being within one or more standard deviations or within ±30%, ±20%, ±15%, ±10%, or ±5% of the stated value. Furthermore, “about”, “approximately”, or “substantially” used herein may choose a more acceptable deviation range or standard deviation according to optical properties, etching properties, or other properties and may not apply one standard deviation to all properties.

Unless otherwise defined, all terms (including technical and scientific terms) used herein have the same meaning as commonly understood by persons skilled in the art to which the disclosure belongs. It should be understood that the terms, such as those defined in commonly used dictionaries, should be interpreted as having meanings consistent with the prior art and the context of the disclosure, and should be interpreted in an idealized or overly formal manner, unless specifically defined herein.

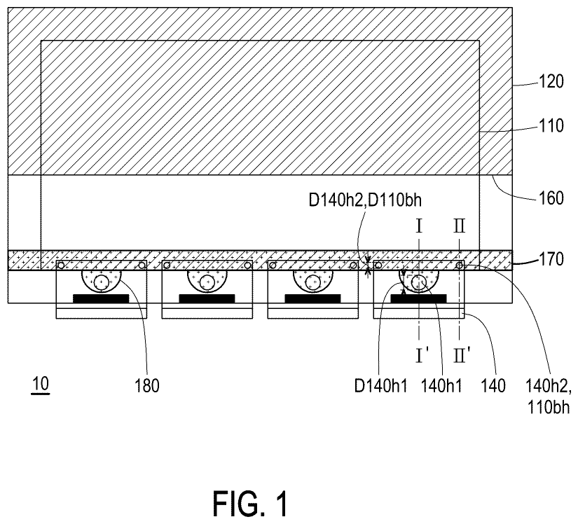

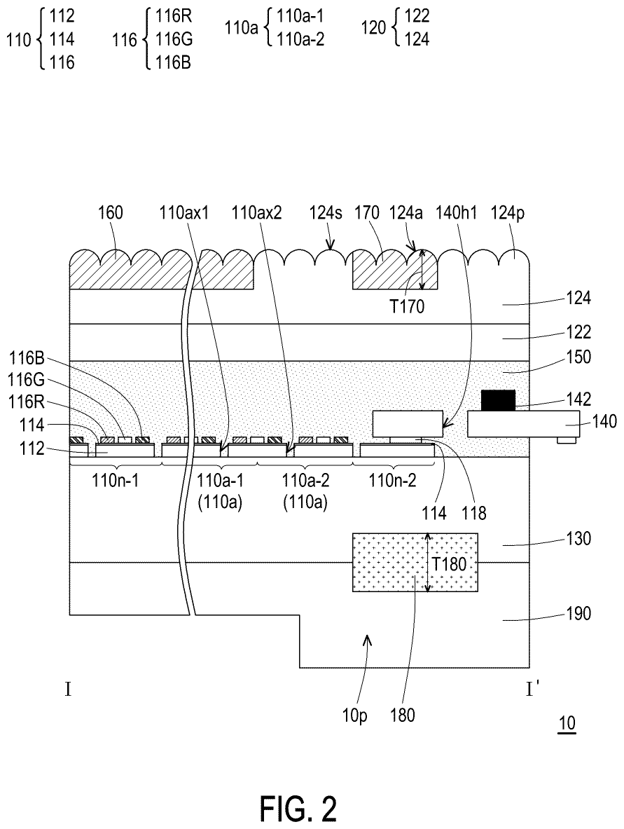

FIG. 1 is a top perspective schematic view of an electronic device according to an embodiment of the disclosure. FIG. 2 is a cross-sectional schematic view of an electronic device according to an embodiment of the disclosure. FIG. 2 corresponds to a section line I-I′ of FIG. 1.

Please refer to FIG. 1 and FIG. 2. An electronic device 10 includes a stretchable electronic component layer 110. In some embodiments, the stretchable electronic component layer 110 includes a stretchable substrate 112, a driving circuit layer 114 disposed on the stretchable substrate 112, and multiple pixel structures 116 electrically connected to the driving circuit layer 114. In some embodiments, each pixel structure 116 may include multiple light emitting components 116R, 116G, and 116B. In some embodiments, the light emitting components 116R, 116G, and 116B are, for example, micro light emitting diodes (μLEDs), but the disclosure is not limited thereto. In some embodiments, the stretchable electronic component layer 110 may be a stretchable display layer. However, the disclosure is not limited thereto, and in other embodiments, the stretchable electronic component layer 110 may also be other types of stretchable component layers or a combination of other types of stretchable component layers and the stretchable display layer.

In some embodiments, the material of the stretchable substrate 112 may be an organic polymer, such as polyimide (PI), polyethylene naphthalate (PEN), polyethylene terephthalate (PET), polycarbonate (PC), polyether sulfone (PES), polyarylate, or other suitable materials, or a combination of at least two of the aforementioned materials, but the disclosure is not limited thereto.

Please refer to FIG. 2. In some embodiments, the stretchable electronic component layer 110 has a stretchable zone 110a, a first non-stretchable zone 110n-1, and a second non-stretchable zone 110n-2, wherein the stretchable zone 110a is located between the first non-stretchable zone 110n-1 and the second non-stretchable zone 110n-2. The second non-stretchable zone 110n-2 has a pad 118, wherein the pad 118 is electrically connected to the driving circuit layer 114. The second non-stretchable zone 110n-2 may also be referred to as a bonding zone.

In some embodiments, the stretchable zone 110a of the stretchable electronic component layer 110 may selectively include a low stretchable zone 110a-1 and a high stretchable zone 110a-2. The strain of the high stretchable zone 110a-2 is greater than the strain of the low stretchable zone 110a-1. For example, in some embodiments, the strain of the first non-stretchable zone 110 n-1 may be less than 1%, the strain of the low stretchable zone 110 a-1 may be less than 6%, and the strain of the high stretchable zone 110 a-2 may be less than 50%, but the disclosure is not limited thereto.

In some embodiments, the high stretchable zone 110a-2 may be located between the low stretchable zone 110a-1 and the second non-stretchable zone 110n-2. In other words, the high stretchable zone 110a-2 may be closer to the bonding zone, and the low stretchable zone 110a-1 may be farther away from the bonding zone. However, the disclosure is not limited thereto. The r elative positions of the low stretchable zone 110a-1, the high stretchable zone 110a-2, and the bonding zone (that is, the second non-stretchable zone 110n-2) depend on the bending state of the electronic device 10, and the disclosure is not limited thereto.

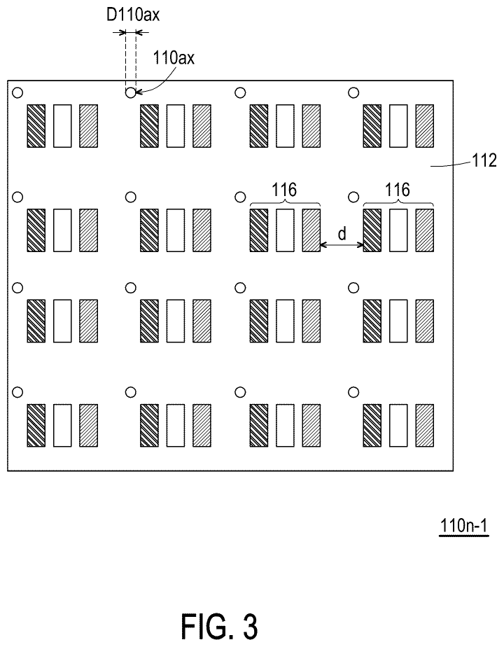

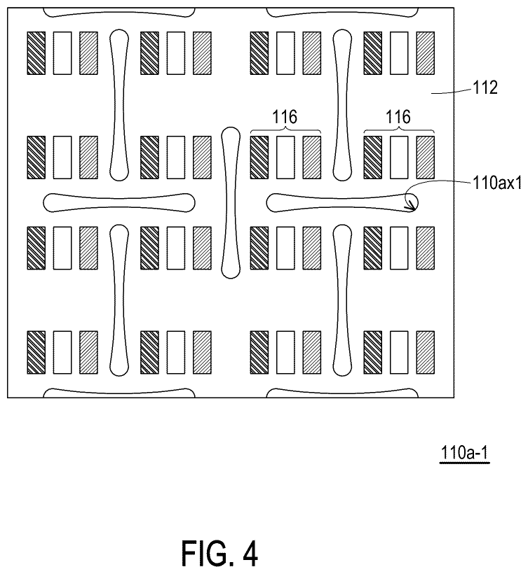

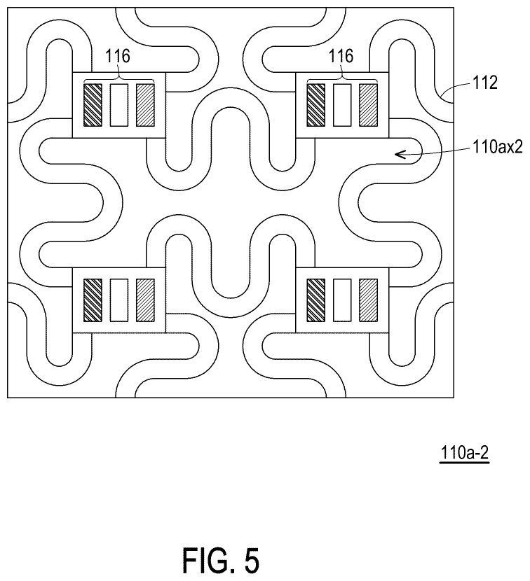

FIG. 3 is a top schematic view of a first non-stretchable zone of a stretchable electronic component layer according to an embodiment of the disclosure. FIG. 4 is a top schematic view of a low stretchable zone of a stretchable electronic component layer according to an embodiment of the disclosure. FIG. 5 is a top schematic view of a high stretchable zone of a stretchable electronic component layer according to an embodiment of the disclosure.

Please refer to FIG. 2, FIG. 3, FIG. 4, and FIG. 5. In some embodiments, the first non-stretchable zone 110n-1 may have a first non-stretchable zone perforation 110ax, and the stretchable zone 110a may have stretchable zone perforations 110ax1 and 110ax2. In some embodiments, the shape of the first non-stretchable zone perforation 110ax may be different from the shapes of the stretchable zone perforations 110ax1 and 110ax2. Furthermore, in some embodiments, the shapes of the stretchable zone perforation 110ax1 of the low stretchable zone 110a-1 and the stretchable zone perforation 110ax2 of the high stretchable zone 110a-2 may be different. For example, in some embodiments, the shape of the first non-stretchable zone perforation 110ax may be substantially circular or other symmetrical shapes (for example, but not limited to, a cross shape), a diameter D110ax of the first non-stretchable zone perforation 110ax may be less than ½ of a shortest distance d between two adjacent pixel structures 116, the stretchable zone perforation 110ax1 of the low stretchable zone 110a-1 may be substantially strip-shaped, and the stretchable zone perforation 110ax2 of the high stretchable zone 110a-2 may be substantially irregularly shaped, but the disclosure is not limited thereto.

Please refer to FIG. 2, FIG. 3, FIG. 4, and FIG. 5. In some embodiments, the stretchable electronic component layer 110 is a stretchable display layer, and the resolution of the first non-stretchable zone 110n-1 of the stretchable display layer is greater than the resolution of the stretchable zone 110a of the stretchable display layer. The low stretchable zone 110a-1 and the high stretchable zone 110a-2 of the stretchable zone 110a of the stretchable display layer are respectively a low stretchable display zone and a high stretchable display zone. The resolution of the low stretchable zone 110a-1 is greater than the resolution of the high stretchable zone 110a-2 and less than the resolution of the first non-stretchable zone 110n-1. In other words, in some embodiments, the stretchable zone 110a with medium resolution (for example, 100 ppi to 200 ppi) may be disposed between the first non-stretchable zone 110n-1 with high resolution (for example, >200 ppi) and the stretchable zone 110a with low resolution (for example, <100 ppi), so as to implement a gradient visual effect.

Please refer to FIG. 1 and FIG. 2. In some embodiments, a decorative component layer 120 may selectively include a first sub-layer 122 and a second sub-layer 124. The first sub-layer 122 is disposed on the stretchable electronic component layer 110, the second sub-layer 124 is disposed on the first sub-layer 122, the first sub-layer 122 is located between the second sub-layer 124 and the stretchable electronic component layer 110, and the second sub-layer 124 has a decorative texture 124a. The second sub-layer 124 of the decorative component layer 120 has a surface 124s facing away from the stretchable electronic component layer 110. The decorative texture 124a is formed on the surface 124s. The decorative texture 124a may provide a tactile sensation. For example, in some embodiments, the decorative texture 124a may be a leather texture, a woven texture, or other textures.

In some embodiments, due to the need to provide the tactile sensation, the second sub-layer 124 may have a haze, wherein the magnitude of the haze depends on the tactile and/or visual effect to be presented, and the disclosure is not limited thereto. For example, if a matte texture effect needs to be provided, the haze of the second sub-layer 124 may fall within a range of 10% to 50%; and if a leather texture effect needs to be provided, the haze of the second sub-layer 124 may fall within a range of 60% to 90%, but the disclosure is not limited thereto. In addition, in some embodiments, without excessively affecting the optical performance, a hardener may be selectively added to the second sub-layer 124 having the decorative texture 124a to adjust the hardness and the surface tactile sensation.

In some embodiments, the transmittance of the first sub-layer 122 is less than the transmittance of the second sub-layer 124. For example, in some embodiments, the transmittance of the first sub-layer 122 may fall within a range of 10% to 40%, and the transmittance of the second sub-layer 124 may be greater than 80%, but the disclosure is not limited thereto. In some embodiments, preferably, the transmittance of the first sub-layer 122 of the decorative component layer 120 falls within a range of 20% to 30%, and the transmittance of the second sub-layer 124 is greater than 92% for an improved appearance and texture, but the disclosure is not limited thereto.

In some embodiments, the colors of the first sub-layer 122 and the second sub-layer 124 of the decorative component layer 120 may be different. For example, in some embodiments, the first sub-layer 122 may have a color (for example, but not limited to, gray, black, etc., and gray or black is preferred for displaying a color balance), and the second sub-layer 124 may be substantially transparent.

In some embodiments, the first sub-layer 122 has a color, and the hue may be adjusted. The second sub-layer 124 is substantially transparent and has the decorative texture 124a to provide the surface tactile sensation. The first sub-layer 122 may be referred to as a color layer. The second sub-layer 124 may be referred to as a transparent texture layer. Through dividing the decorative component layer 120 into the color layer and the transparent texture layer, the visual effect of the electronic device 10 may be improved. For example, in some embodiments, since the decorative texture 124a is formed of a transparent material, a difference in thickness of the decorative texture 124a does not cause color spots, and the visual effect of the electronic device 10 may be improved.

Please refer to FIG. 2. In some embodiments, the electronic device 10 further includes a carrier board layer 130, wherein the stretchable electronic component layer 110 is disposed on the carrier board layer 130, and the stretchable electronic component layer 110 is located between the decorative component layer 120 and the carrier board layer 130. For example, in some embodiments, the main material of the carrier board layer 130 may be silicone rubber, and the Young's modulus of the carrier board layer 130 may be between 0.5 MPa and 50 MPa. Preferably, the Young's modulus of the carrier board layer 130 is between 1 MPa and 10 MPa. In some embodiments, the stretch recovery rate of the carrier board layer 130 may be less than 5%. Preferably, the stretch recovery rate of the carrier board layer 130 is less than 2%, but the disclosure is not limited thereto.

Please refer to FIG. 1 and FIG. 2. In some embodiments, the electronic device 10 further includes a flexible electronic component 140 bonded to the second non-stretchable zone 110n-2 of the stretchable electronic component layer 110. In detail, the flexible electronic component 140 is bonded to the pad 118 of the second non-stretchable zone 110n-2. For example, in some embodiments, the flexible electronic component 140 may include a chip 142, wherein the chip 142 may be bonded to the stretchable electronic component layer 110 via a chip on film (COF). However, the disclosure is not limited thereto, and in other embodiments, the flexible electronic component 140 may also be other types of flexible components.

In some embodiments, the electronic device 10 further includes a protective layer 150 disposed on the carrier board layer 130 and covering the stretchable electronic component layer 110 and a part of the flexible electronic component 140, wherein the protective layer 150 is located between the decorative component layer 120 and the stretchable electronic component layer 110 and between the decorative component layer 120 and the flexible electronic component 140. In some embodiments, the protective layer 150 may cover the chip 142 of the flexible electronic component 140, but the disclosure is not limited thereto.

In some embodiments, the main material of the decorative component layer 120 and the material of the protective layer 150 may be the same, so that a difference in refractive index between the decorative component layer 120 and the protective layer 150 is less than 0.05. For example, in some embodiments, the main material of the decorative component layer 120 and the material of the protective layer 150 may include silicone rubber, but the disclosure is not limited thereto. In some embodiments, the Young's moduli of the decorative component layer 120 and the protective layer 150 may be between 0.5 MPa and 50 MPa. Preferably, the Young's moduli of the decorative component layer 120 and the protective layer 150 is between 1 MPa and 10 MPa, but the disclosure is not limited thereto. In some embodiments, the stretch rate of the decorative component layer 120 and the protective layer 150 may fall within a range of 600% to 800%, but the disclosure is not limited thereto. In some embodiments, the stretch recovery rates of the decorative component layer 120 and the protective layer 150 may be less than 5%. Preferably, the stretch recovery rates of the decorative component layer 120 and the protective layer 150 is less than 2%, but the disclosure is not limited thereto.

In some embodiments, the electronic device 10 further includes a sensing layer 190. The carrier board layer 130 is located between the stretchable electronic component layer 110 and the sensing layer 190. In some embodiments, the sensing layer 190 is, for example, a touch sensing layer, but the disclosure is not limited thereto. In some embodiments, the material of a main base layer of the sensing layer 190 may be silicone rubber, and the Young's modulus of the sensing layer 190 may be between 0.5 MPa and 50 MPa. Preferably, the Young's modulus of the sensing layer 190 is between 1 MPa and 10 MPa. In some embodiments, the stretch recovery rate of the sensing layer 190 may be less than 5%. Preferably, the stretch recovery rate of the sensing layer 190 is less than 2%, but the disclosure is not limited thereto.

Please refer to FIG. 1 and FIG. 2. In some embodiments, the flexible electronic component 140 has a first perforation 140h1, and the first perforation 140h1 is located outside the second non-stretchable zone 110n-2 of the stretchable electronic component layer 110. In particular, a part of the protective layer 150 is filled in the first perforation 140h1 of the flexible electronic component 140 and is connected to the carrier board layer 130. The part of the protective layer 150 filled in the first perforation 140h1 of the flexible electronic component 140 has a limiting/fixing effect and may limit/fix the relative positions of the flexible electronic component 140, the protective layer 150, and the carrier board layer 130.

Please refer to FIG. 1. In some embodiments, the shape of the first perforation 140h1 may be circular to prevent uneven stress when stretched. In some embodiments, a dimension D140h1 of the first perforation 140h1 may fall within a range of 2 mm to 10 mm. Preferably, the dimension D140h1 of the first perforation 140h1 is between 6 mm and 8 mm, but the disclosure is not limited thereto.

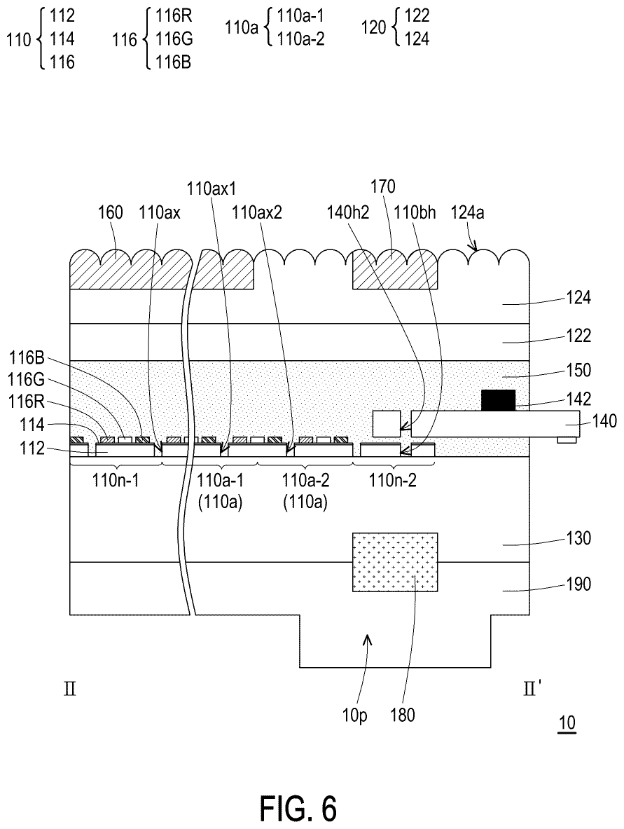

FIG. 6 is a cross-sectional schematic view of an electronic device according to an embodiment of the disclosure. FIG. 6 corresponds to a section line II-II′ of FIG. 1. Please refer to FIG. 1 and FIG. 6. In some embodiments, the flexible electronic component 140 has a second perforation 140h2, the second non-stretchable zone 110n-2 of the stretchable electronic component layer 110 has a second non-stretchable zone perforation 110bh, and the second perforation 140h2 of the flexible electronic component 140 is disposed corresponding to the second non-stretchable zone perforation 110bh of the stretchable electronic component layer 110. The second perforation 140h2 of the flexible electronic component 140 substantially overlaps with the second non-stretchable zone perforation 110bh of the stretchable electronic component layer 110. A part of the protective layer 150 is filled in the second perforation 140h2 of the flexible electronic component 140 and the second non-stretchable zone perforation 110bh of the stretchable electronic component layer 110 and is connected to the carrier board layer 130. The part of the protective layer 150 filled in the second perforation 140h2 of the flexible electronic component 140 and the second non-stretchable zone perforation 110bh of the stretchable electronic component layer 110 has a limiting/fixing effect and may limit/fix the relative positions of the flexible electronic component 140, the protective layer 150, the stretchable electronic component layer 110, and the carrier board layer 130.

Please refer to FIG. 1. In some embodiments, the shape of the second perforation 140h2/the second non-stretchable zone perforation 110bh may be circular to prevent uneven stress when stretched. In some embodiments, a dimension D140h2/D110bh of the second perforation 140h2/the second non-stretchable zone perforation 110bh may fall within a range of 0.1 mm to 2.0 mm. Preferably, the dimension D140h2/D110bh of the second perforation 140h2/the second non-stretchable zone perforation 110bh is between 0.6 mm and 1.2 mm, but the disclosure is not limited thereto. Please refer to FIG. 1 and FIG. 2. In some embodiments, the electronic device 10 may be assembled onto a curved surface (not shown) of a fixture, and the second perforation 140h2 and/or the second non-stretchable zone perforation 110bh may be used to fix the entire electronic device 10 onto the curved surface of the fixture.

Please refer to FIG. 2. In some embodiments, a part of the protective layer 150 may be filled in the first non-stretchable zone perforation 110ax, the stretchable zone perforation 110ax1, and the stretchable zone perforation 110ax2 of the stretchable electronic component layer 110. The part of the protective layer 150 filled in the first non-stretchable zone perforation 110ax, the stretchable zone perforation 110ax1, and the stretchable zone perforation 110ax2 has a limiting/fixing effect and may limit/fix the relative positions of the protective layer 150, the stretchable electronic component layer 110, and the carrier board layer 130.

Please refer to FIG. 1, FIG. 2, and FIG. 6. It should be noted that the electronic device 10 further includes a transparent hard board layer 160 and an upper hard board layer 170. The transparent hard board layer 160 is embedded or buried in the decorative component layer 120 and overlaps with the first non-stretchable zone 110n-1 of the stretchable electronic component layer 110. The upper hard board layer 170 is embedded or buried in the decorative component layer 120 and overlaps with the second non-stretchable zone 110n-2 of the stretchable electronic component layer 110. The upper hard board layer 170 may be transparent, translucent, or opaque. The transparent hard board layer 160 and the upper hard board layer 170 may suppress the deformation of the electronic device 100 and improve issues such as separation of internal films and irregular warpage.

Please refer to FIG. 2. In some embodiments, in addition to overlapping with the first non-stretchable zone 110n-1, the transparent hard board layer 160 may also selectively overlap with a part of the stretchable zone 110a. In some embodiments, the upper hard board layer 170 partially overlaps with the flexible electronic component 140. In some embodiments, the upper hard board layer 170 may overlap with the pad 118 of the second non-stretchable zone 110n-2 of the stretchable electronic component layer 110. In other words, in some embodiments, the upper hard board layer 170 at least overlaps with a junction between the flexible electronic component 140 and the stretchable electronic component layer 110.

In some embodiments, the material of the transparent hard board layer 160 may be polyethylene terephthalate (PET), polymethyl methacrylate (PMMA), polycarbonate (PC), polyethylene naphthalate (PEN), triacetyl cellulose (TAC), cyclic olefin polymer (COP), etc. Preferably, polyethylene terephthalate (PET), polycarbonate (PC), and cyclic olefin polymer (COP) materials with higher temperature resistance are used. In some embodiments, if used in conjunction with the light emitting components 116R, 116G, 116B that may provide polarized light, the material of the transparent hard board layer 160 may be a material that has substantially no phase retardation, such as triacetyl cellulose (TAC) or cyclic olefin polymer (COP).

Please refer to FIG. 1, FIG. 2, and FIG. 6. In some embodiments, the electronic device 10 may further include a lower hard board layer 180, wherein the carrier board layer 130 is located between the stretchable electronic component layer 110 and the lower hard board layer 180, and the lower hard board layer 180 overlaps with the second non-stretchable zone 110n-2 of the stretchable electronic component layer 110. The lower hard board layer 180 may be transparent, translucent, or opaque. In some embodiments, the lower hard board layer 180 may overlap with the pad 118 of the second non-stretchable zone 110n-2 of the stretchable electronic component layer 110. In other words, in some embodiments, the lower hard board layer 180 at least overlaps with the junction between the flexible electronic component 140 and the stretchable electronic component layer 110. The upper hard board layer 170 and the lower hard board layer 180 overlap at least where the pad 118 is located.

Please refer to FIG. 2 and FIG. 6. In some embodiments, a part of the lower hard board layer 180 may be embedded in the carrier board layer 130, and a part of the lower hard board layer 180 may protrude from the carrier board layer 130. The protruding part of the lower hard board layer 180 may enable the electronic device 10 to have a protruding portion 10p, and the protruding portion 10p may be used to limit other mechanisms. In some embodiments, the lower hard board layer 180 may be disposed between the carrier board layer 130 and the sensing layer 190, and embedded in the carrier board layer 130 and the sensing layer 190, but the disclosure is not limited thereto. In another embodiment, the entire lower hard board layer 180 may be buried in the carrier board layer 130 or the sensing layer 190.

Please refer to FIG. 2. In some embodiments, a thickness T180 of the lower hard board layer 180 may be greater than a thickness T170 of the upper hard board layer 170 to provide improved protection. Please refer to FIG. 1 and FIG. 2. In some embodiments, the first perforation 140h1 of the flexible electronic component 140 overlaps with at least one of the upper hard board layer 170 and the lower hard board layer 180. Please refer to FIG. 1 and FIG. 6. In some embodiments, the second perforation 140h2 of the flexible electronic component 140 and the second non-stretchable zone perforation 110bh of the stretchable electronic component layer 110 overlap with the upper hard board layer 170 and the lower hard board layer 180.

In some embodiments, in addition to selecting the same material as the transparent hard board layer 160, the material of the lower hard board layer 180 may also be opaque resin (acrylonitrile butadiene styrene, ABS), polylactic acid (PLA), polypropylene (PP), nylon, or other high-temperature composite materials (for example, PLA-CF, PA-CF, etc.).

It must be noted here that the following embodiments continue to use the reference numerals and some content of the foregoing embodiment, wherein the same reference numerals are adopted to represent the same or similar components, and the description of the same technical content is omitted. Reference may be made to the foregoing embodiment for the description of the omitted part, which will not be repeated in the following embodiments.

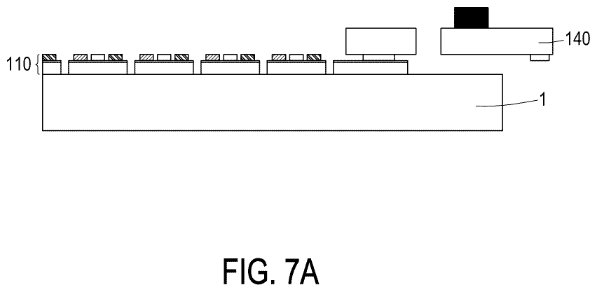

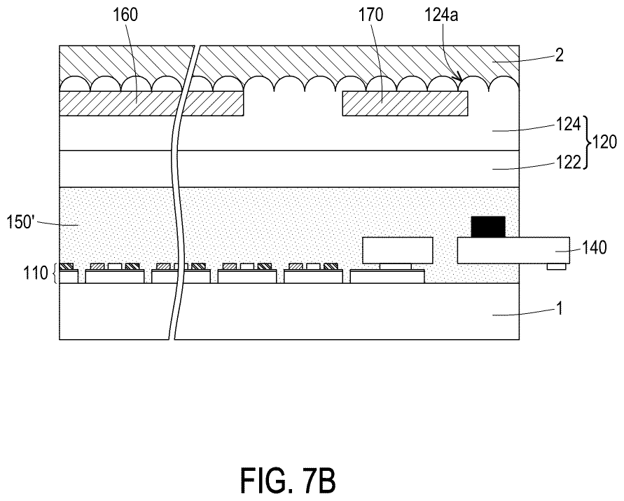

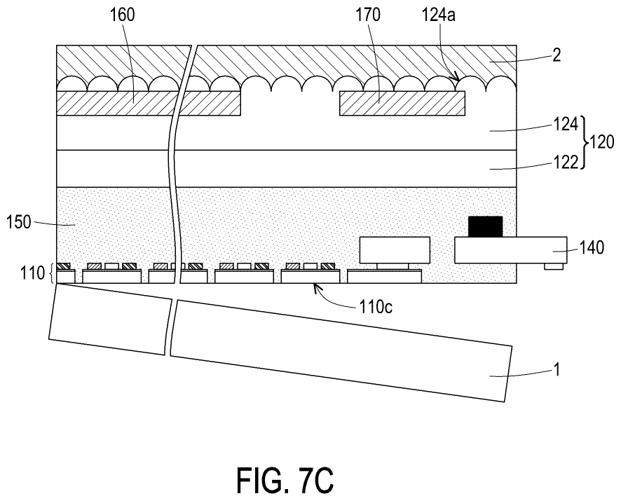

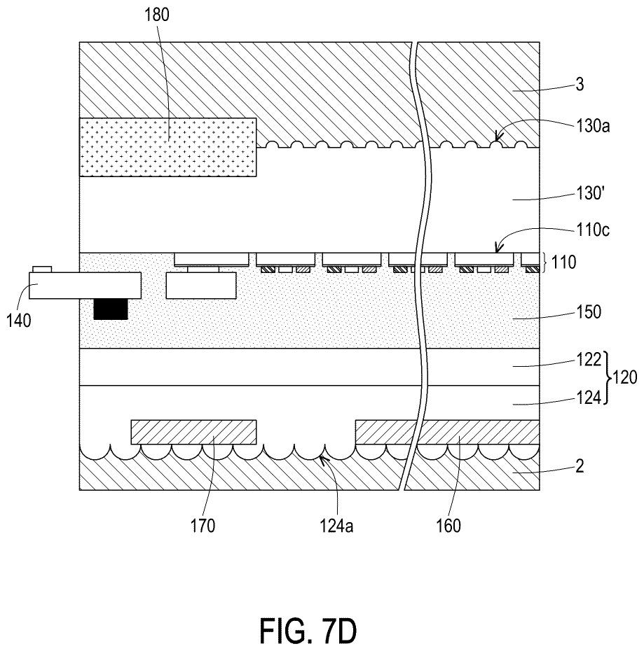

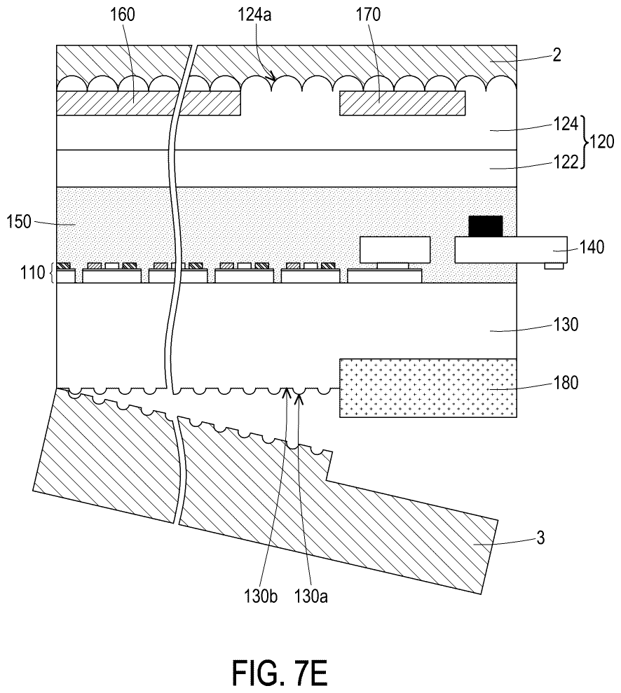

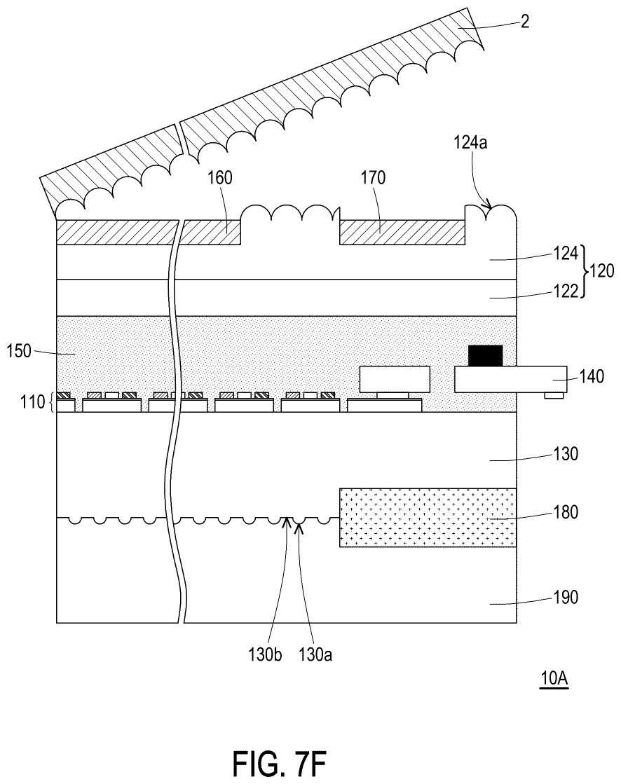

FIG. 7A to FIG. 7F are cross-sectional schematic views of a manufacturing process of an electronic device according to another embodiment of the disclosure. Please refer to FIG. 7A. First, the stretchable electronic component layer 110 is formed on a hard carrier board 1, and the flexible electronic component 140 is bonded to the stretchable electronic component layer 110. Please refer to FIG. 7B. Next, a protective layer 150′ is formed on the stretchable electronic component layer 110, wherein the protective layer 150′ is not yet mature. Please refer to FIG. 7B. Next, the decorative component layer 120 and a texture film 2 for manufacturing the decorative texture 124a are laminated on the mature protective layer 150′ that is not yet mature, and the transparent hard board layer 160 and the upper hard board layer 170 are sandwiched between the texture film 2 and the decorative component layer 120.

Please refer to FIG. 7B and FIG. 7C. Next, a heating procedure is performed to form the mature protective layer 150, wherein the mature protective layer 150 is fixedly connected to the decorative component layer 120, and the mature protective layer 150 is fixedly connected to the transparent hard board layer 160 and the upper hard board layer 170. Please refer to FIG. 7C. Next, the hard carrier board 1 and the stretchable electronic component layer 110 are separated to expose a surface 110c of the stretchable electronic component layer 110.

Please refer to FIG. 7D. Next, a carrier board layer 130′ is formed on the surface 110c of the stretchable electronic component layer 110, and a texture film 3 is selectively used to form a texture 130a on the carrier board layer 130′ that is not mature. In addition, the lower hard board layer 180 is sandwiched between the carrier board layer 130′ and the texture film 3. Please refer to FIG. 7D and FIG. 7E. Next, a heating procedure is performed to form the mature carrier board layer 130, wherein the mature carrier board layer 130 is fixedly connected to the stretchable electronic component layer 110 and the protective layer 150, and the mature carrier board layer 130 is fixedly connected to the lower hard board layer 180. Please refer to FIG. 7E and FIG. 7F. Next, the carrier board layer 130 and the texture film 3 are separated to expose a surface 130b of the carrier board layer 130, and the decorative component layer 120, the transparent hard board layer 160, the upper hard board layer 170, and the texture film 2 are separated. Please refer to FIG. 7F. Next, the sensing layer 190 is formed on the surface 130b of the carrier board layer 130 and the lower hard board layer 180. So far, an electronic device 10A is completed.

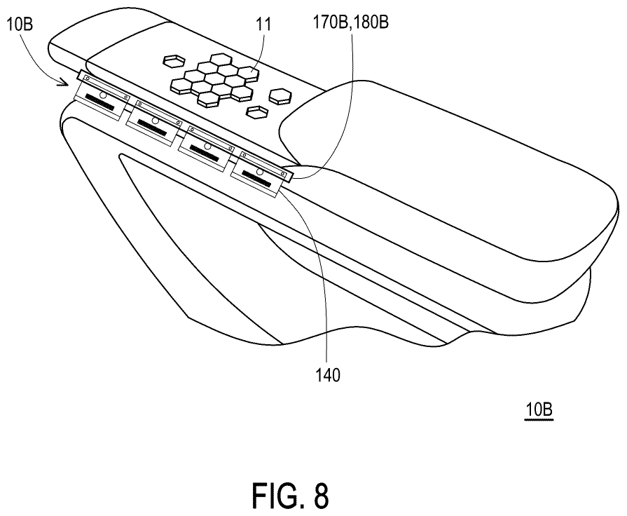

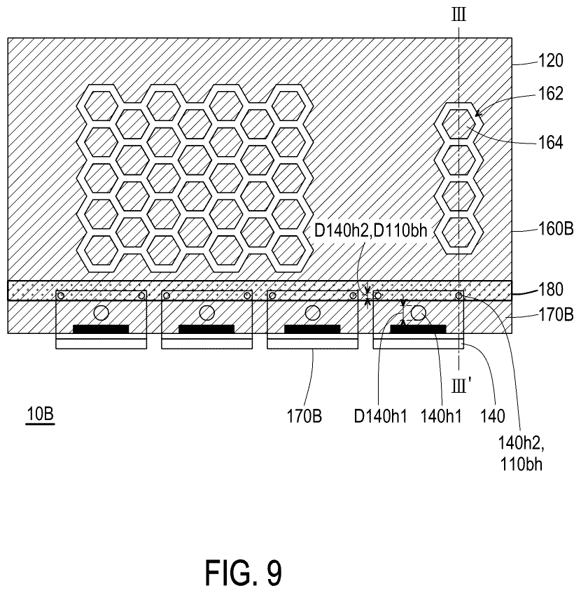

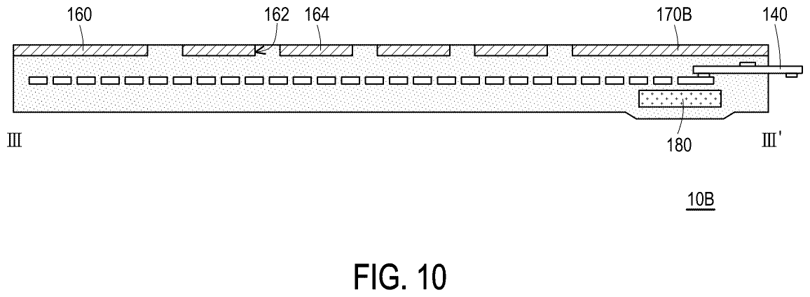

FIG. 8 shows an application scenario of an electronic device according to yet another embodiment of the disclosure. FIG. 9 is a top perspective schematic view of an electronic device according to yet another embodiment of the disclosure. FIG. 10 is a cross-sectional schematic view of an electronic device according to yet another embodiment of the disclosure. FIG. 10 corresponds to a section line III-III′ of FIG. 9.

Please refer to FIG. 8, FIG. 9, and FIG. 10. An electronic device 10B of the embodiment is similar to the electronic device 10, and the difference between the two is that a transparent hard board layer 160B and an upper hard board layer 170B of the electronic device 10B of the embodiment are different from the transparent hard board layer 160 and the upper hard board layer 170 of the electronic device 10 of the foregoing embodiment.

Please refer to FIG. 8, FIG. 9, and FIG. 10. Specifically, in the embodiment, the transparent hard board layer 160B and the upper hard board layer 170B may be multiple parts of the same connecting board body. In the embodiment, the transparent hard board layer 160B may have an opening 162 to define multiple island portions 164 of the transparent hard board layer 160B. In the embodiment, the island portions 164 of the transparent hard board layer 160B may correspond to multiple dynamic buttons 11 of the electronic device 10B to limit stretching. In the embodiment, the electronic device 10B may be, for example, installed on an armrest in a vehicle, but the disclosure is not limited thereto.

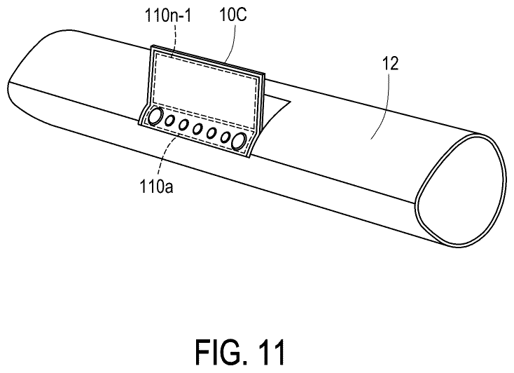

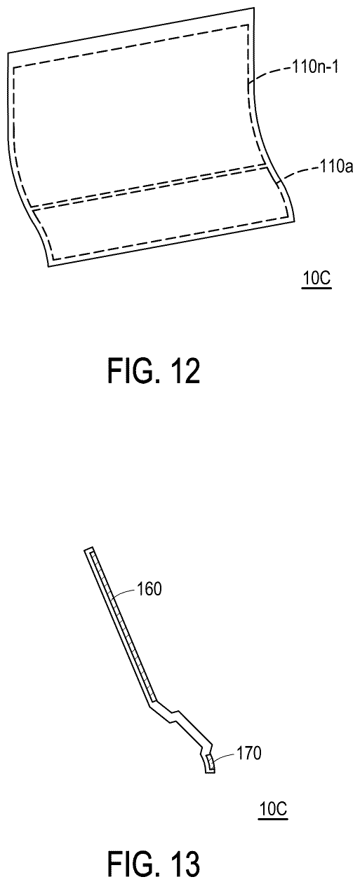

FIG. 11 shows an application scenario of an electronic device according to still another embodiment of the disclosure. FIG. 12 is a side schematic view of an electronic device according to still another embodiment of the disclosure. FIG. 13 is a cross-sectional schematic view of an electronic device according to yet another embodiment of the disclosure.

Please refer to FIG. 11, FIG. 12, and FIG. 13. An electronic device 10C of the embodiment is similar to the electronic device 10. In the embodiment, the stretchable zone 110a of the electronic device 10C may correspond to a button zone of the electronic device 10B, and the first non-stretchable zone 110n-1 of the electronic device 10C may correspond to a non-button zone and/or a high-resolution display zone of the electronic device 10B. In the embodiment, the electronic device 10C may be, for example, installed in a center console 12 in a vehicle and may be raised from the center console 12 to perform display or other functions or may be retracted into the center console 12 and present a surface texture that is the same as or similar to the surface of the center console 12, but the disclosure is not limited thereto.

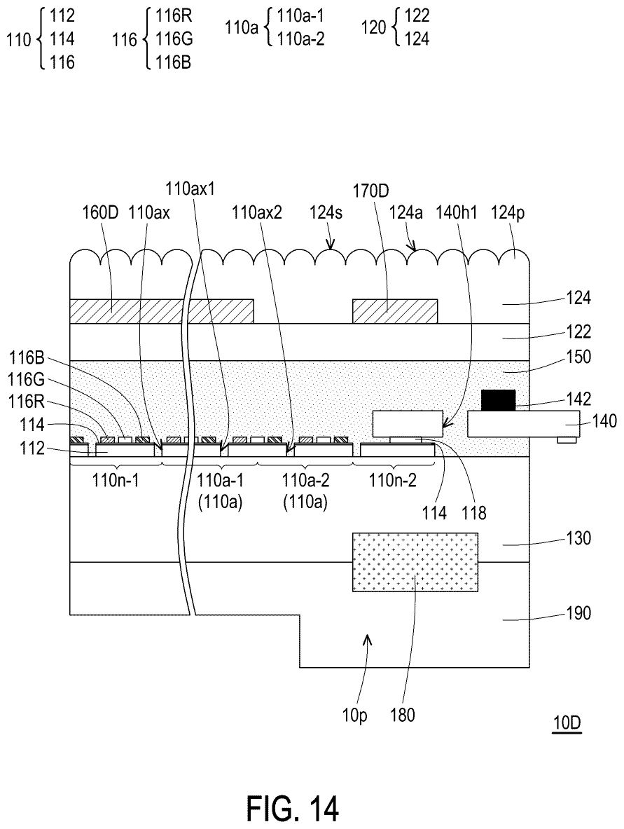

FIG. 14 is a cross-sectional schematic view of an electronic device according to an embodiment of the disclosure. Please refer to FIG. 14. An electronic device 10D of the embodiment is similar to the electronic device 10, and the difference between the two is that a transparent hard board layer 160D and an upper hard board layer 170D of the electronic device 10D of the embodiment are different from the transparent hard board layer 160 and the upper hard board layer 170 of the electronic device 10 of the foregoing embodiment. Please refer to FIG. 13. Specifically, in the embodiment, the transparent hard board layer 160D and the upper hard board layer 170D are buried in the decorative component layer 120. For example, in the embodiment, the transparent hard board layer 160D and the upper hard board layer 170D are sandwiched between the first sub-layer 122 and the second sub-layer 124 of the decorative component layer 120, but the disclosure is not limited thereto.

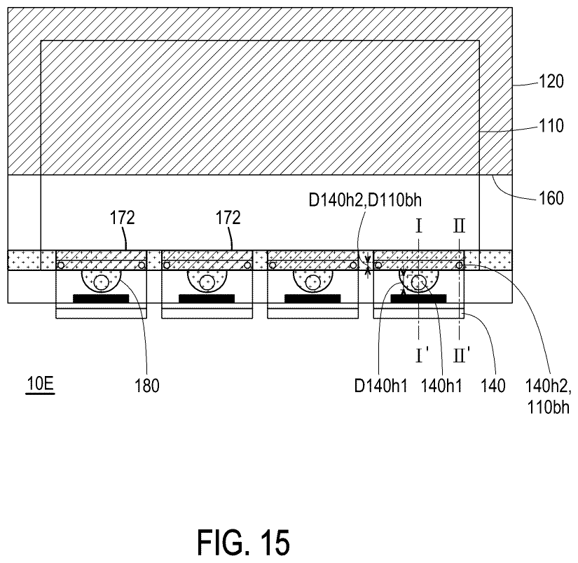

FIG. 15 is a top perspective schematic view of an electronic device according to another embodiment of the disclosure. An electronic device 10E of FIG. 15 is similar to the electronic device 10 of FIG. 1, and the difference between the two is that in the embodiment of FIG. 15, the routing of the stretchable electronic component layer 110 is partitioned and/or has a stretching design, and the upper hard board layer 170 also correspondingly has a partition design. Please refer to FIG. 15. For example, in some embodiments, an upper hard board layer 170E may include multiple upper sub-hard board layers 172 separated from each other. Furthermore, the upper sub-hard board layers 172 may respectively overlap at multiple junctions between multiple flexible electronic components 140 and the stretchable electronic component layer 110.

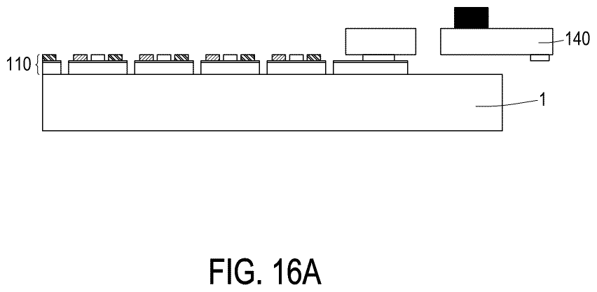

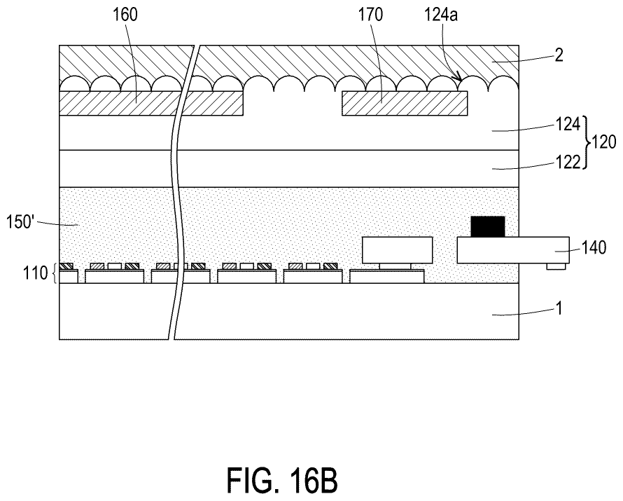

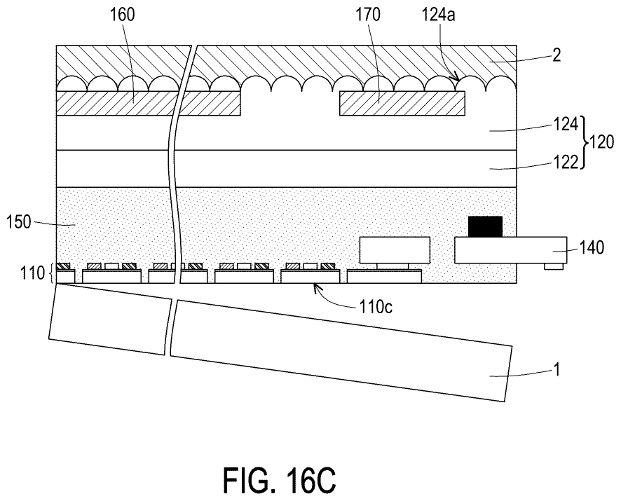

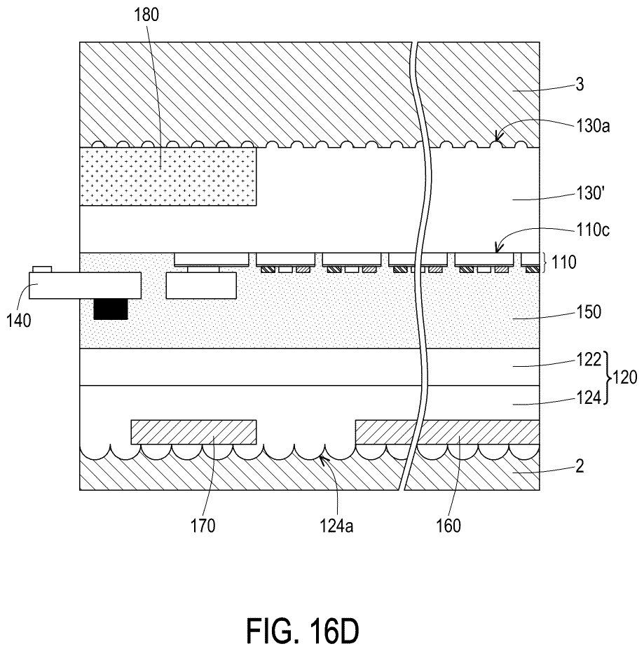

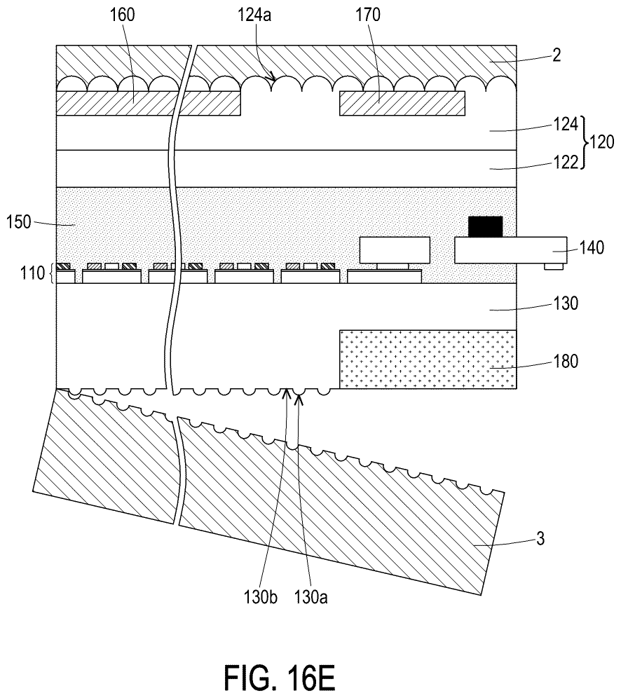

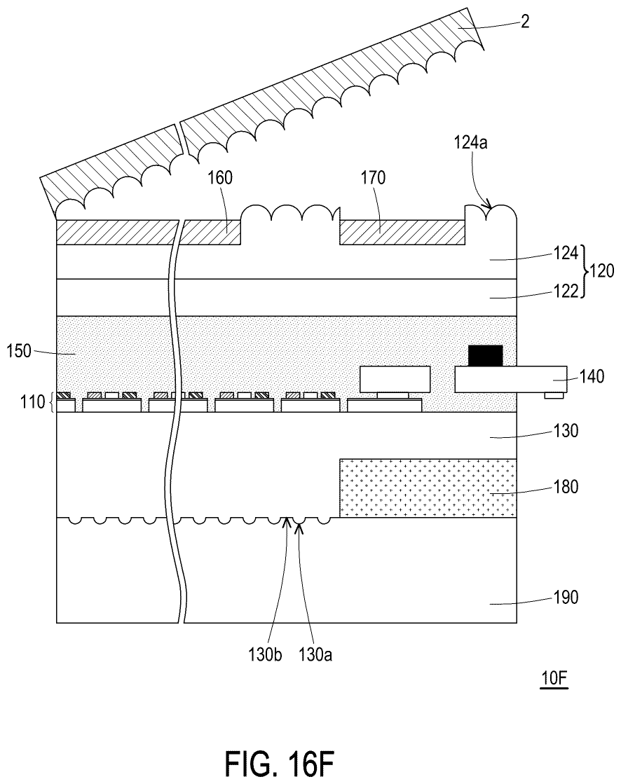

FIG. 16A to FIG. 16F are cross-sectional schematic views of a manufacturing process of an electronic device according to yet another embodiment of the disclosure. An electronic device 10F and a manufacturing process thereof of FIG. 16A to FIG. 16F are similar to the electronic device 10A and the manufacturing process thereof of FIG. 7A to FIG. 7F, and the difference between the two is that in the embodiment of FIG. 16A to FIG. 16F, the lower hard board layer 180 does not protrude from the surface 130b of the carrier board layer 130.

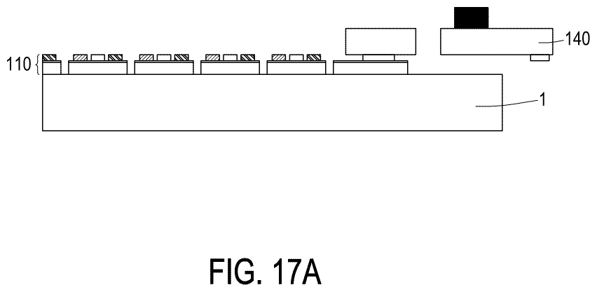

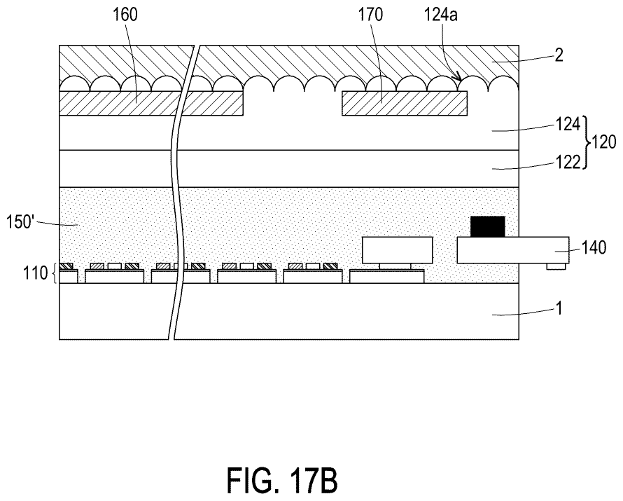

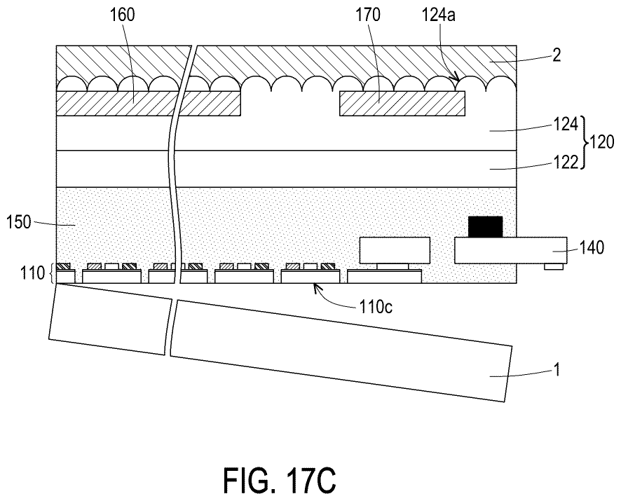

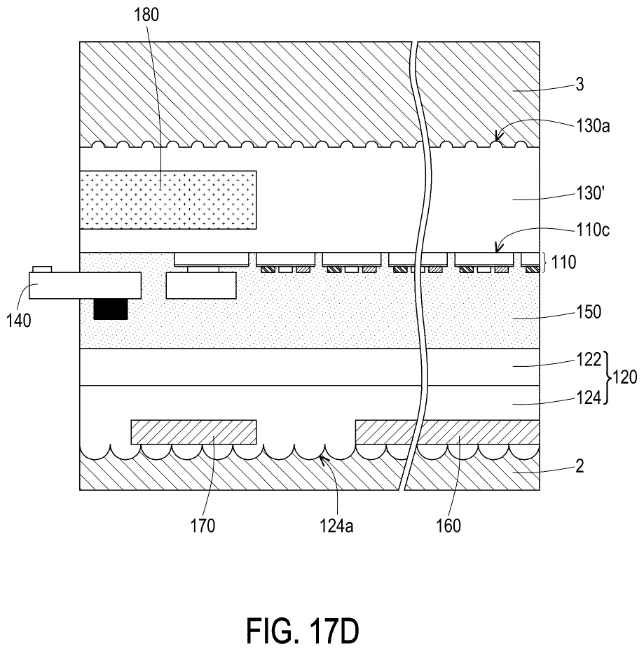

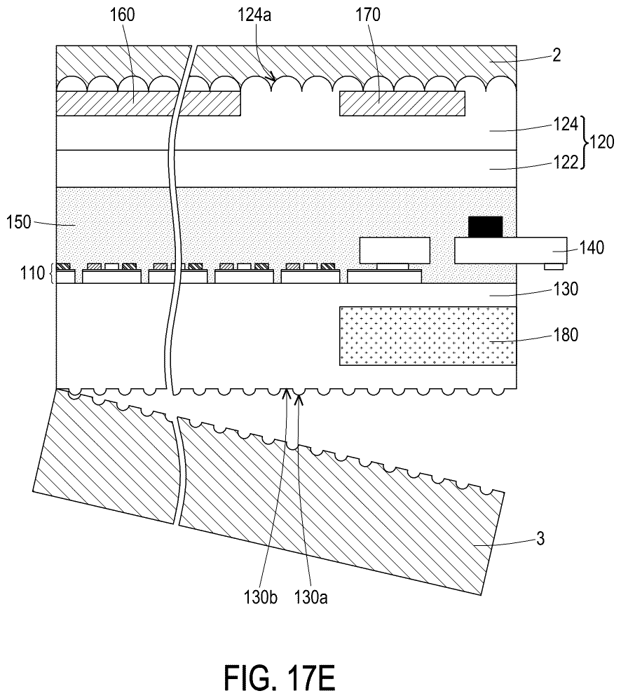

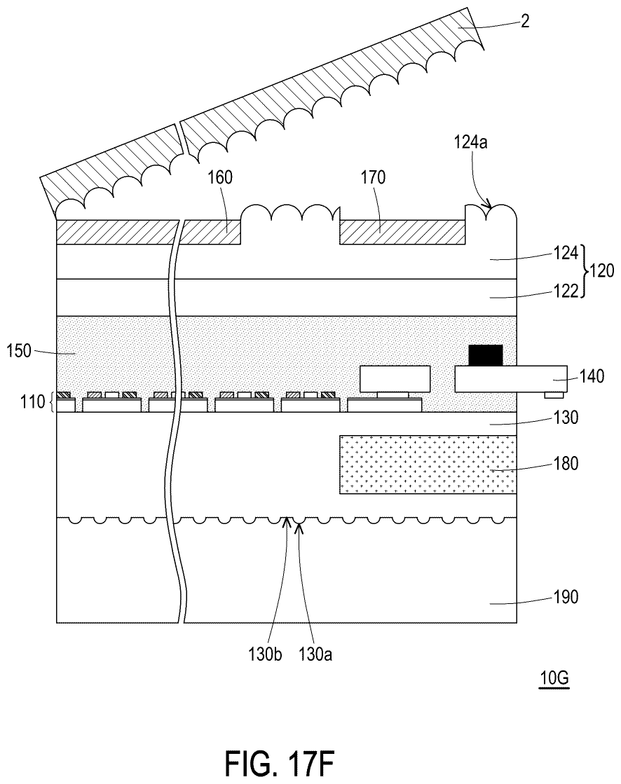

FIG. 17A to FIG. 17F are cross-sectional schematic views of a manufacturing process of an electronic device according to still another embodiment of the disclosure. An electronic device 10G and a manufacturing process thereof of FIG. 17A to FIG. 17F are similar to the electronic device 10A and the manufacturing process thereof of FIG. 7A to FIG. 7F, and the difference between the two is that in the embodiment of FIG. 17A to FIG. 17F, the lower hard board layer 180 is buried in the carrier board layer 130.

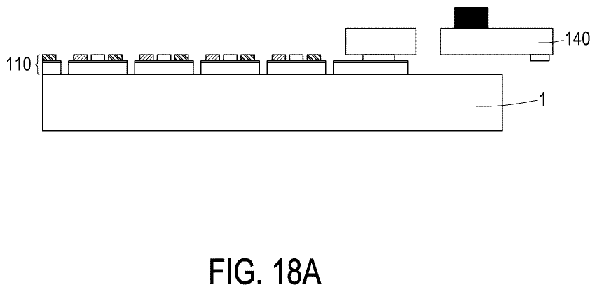

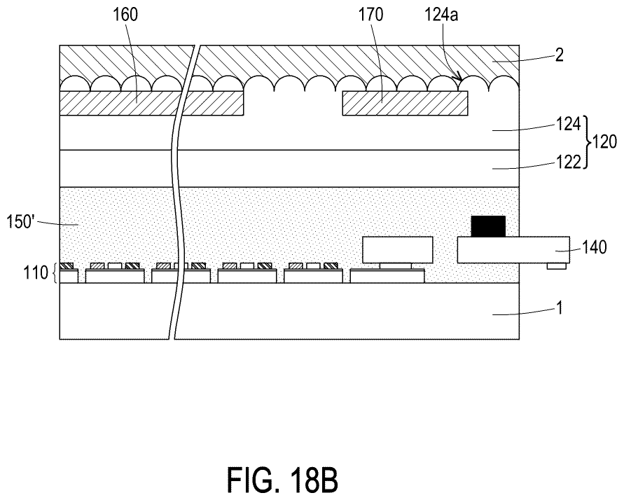

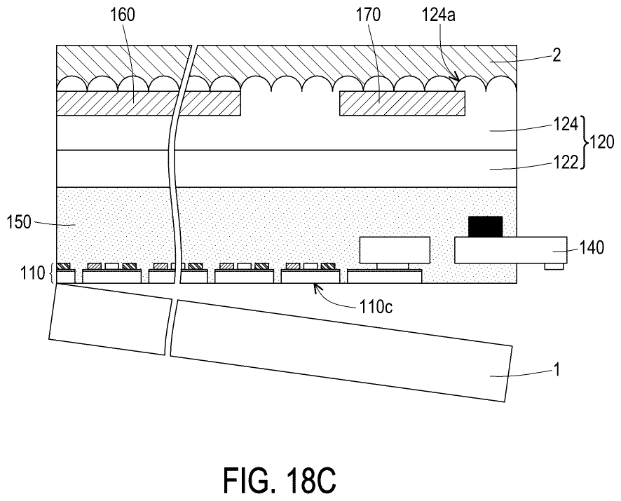

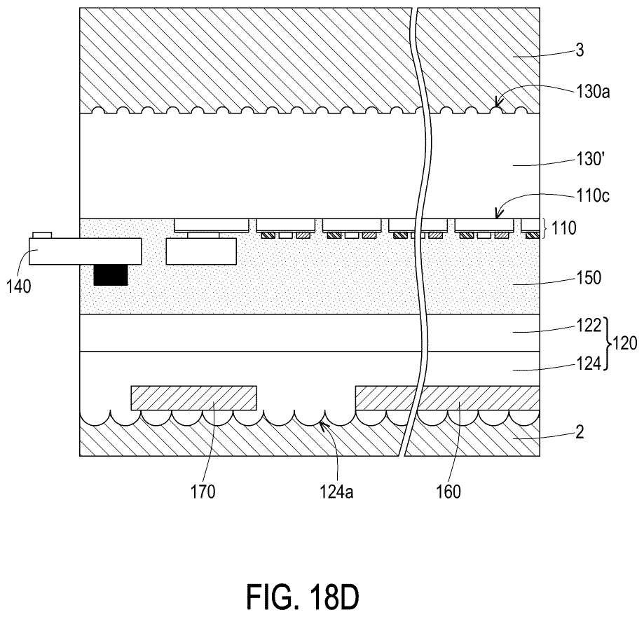

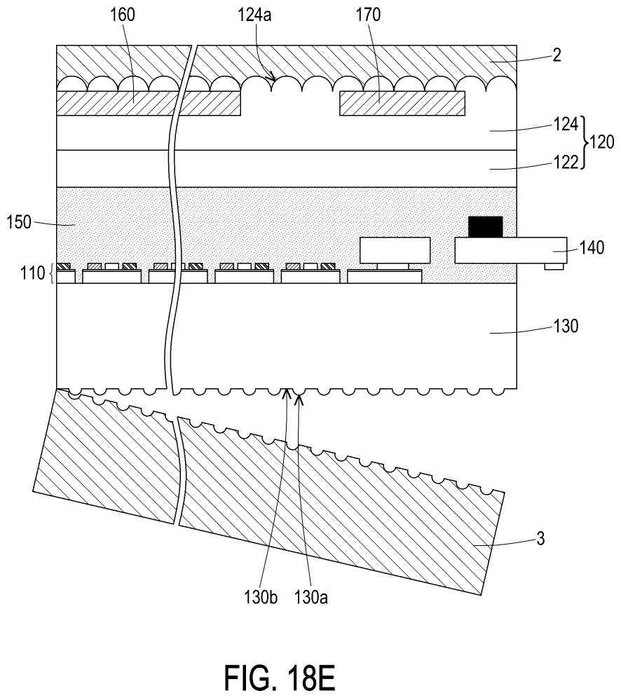

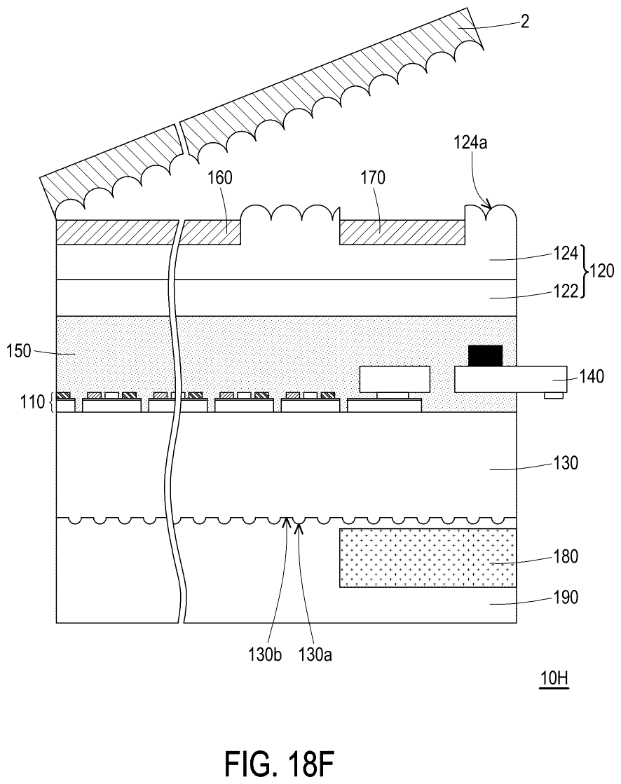

FIG. 18A to FIG. 18F are cross-sectional schematic views of a manufacturing process of an electronic device according to an embodiment of the disclosure. An electronic device 10H and a manufacturing process thereof of FIG. 18A to FIG. 18F are similar to the electronic device 10A and the manufacturing process thereof of FIG. 7A to FIG. 7F, and the difference between the two is that in the embodiment of FIG. 18A to FIG. 18F, the lower hard board layer 180 is buried in the sensing layer 190.

What is claimed is:

1. An electronic device, comprising:
a stretchable electronic component layer, having a stretchable zone, a first non-stretchable zone, and a second non-stretchable zone, wherein the stretchable zone is located between the first non-stretchable zone and the second non-stretchable zone;
a decorative component layer, disposed on the stretchable electronic component layer;
a transparent hard board layer, embedded or buried in the decorative component layer and overlapping with the first non-stretchable zone of the stretchable electronic component layer; and
an upper hard board layer, embedded or buried in the decorative component layer and overlapping with the second non-stretchable zone of the stretchable electronic component layer.

2. The electronic device according to claim 1, further comprising:
a flexible electronic component, bonded to a pad of the second non-stretchable zone of the stretchable electronic component layer, wherein the upper hard board layer partially overlaps with the flexible electronic component.

3. The electronic device according to claim 2, wherein the upper hard board layer overlaps with the pad of the second non-stretchable zone of the stretchable electronic component layer.

4. The electronic device according to claim 1, wherein the transparent hard board layer further overlaps a part of the stretchable zone of the stretchable electronic component layer.

5. The electronic device according to claim 1, wherein the stretchable electronic component layer is a stretchable display layer, and resolution of the first non-stretchable zone of the stretchable display layer is greater than resolution of the stretchable zone of the stretchable display layer.

6. The electronic device according to claim 5, wherein the stretchable zone of the stretchable display layer comprises a low stretchable display zone and a high stretchable display zone, and resolution of the low stretchable display zone is greater than resolution of the high stretchable display zone and less than the resolution of the first non-stretchable zone.

7. The electronic device according to claim 1, further comprising:
a carrier board layer, wherein the stretchable electronic component layer is disposed on the carrier board layer, and the stretchable electronic component layer is located between the decorative component layer and the carrier board layer; and
a lower hard board layer, wherein the carrier board layer is located between the stretchable electronic component layer and the lower hard board layer, and the lower hard board layer overlaps with the second non-stretchable zone of the stretchable electronic component layer.

8. The electronic device according to claim 7, further comprising:
a flexible electronic component, bonded to a pad of the second non-stretchable zone of the stretchable electronic component layer, wherein the upper hard board layer and the lower hard board layer overlap at least where the pad is located.

9. The electronic device according to claim 7, wherein a thickness of the lower hard board layer is greater than a thickness of the upper hard board layer.

10. The electronic device according to claim 1, wherein the first non-stretchable zone of the stretchable electronic component layer has a first non-stretchable zone perforation, the electronic device further comprising:
a carrier board layer, wherein the stretchable electronic component layer is disposed on the carrier board layer, and the stretchable electronic component layer is located between the decorative component layer and the carrier board layer; and
a protective layer, disposed on the carrier board layer and covering the stretchable electronic component layer, wherein the protective layer is located between the decorative component layer and the stretchable electronic component layer;
wherein a part of the protective layer is filled in the first non-stretchable zone perforation of the stretchable electronic component layer and is connected to the carrier board layer.

11. The electronic device according to claim 1, wherein the stretchable zone of the stretchable electronic component layer has a stretchable zone perforation, the electronic device further comprising:
a carrier board layer, wherein the stretchable electronic component layer is disposed on the carrier board layer, and the stretchable electronic component layer is located between the decorative component layer and the carrier board layer; and
a protective layer, disposed on the carrier board layer and covering the stretchable electronic component layer, wherein the protective layer is located between the decorative component layer and the stretchable electronic component layer;
wherein a part of the protective layer is filled in the stretchable zone perforation of the stretchable electronic component layer and is connected to the carrier board layer.

12. The electronic device according to claim 1, further comprising:
a carrier board layer, wherein the stretchable electronic component layer is disposed on the carrier board layer, and the stretchable electronic component layer is located between the decorative component layer and the carrier board layer;
a flexible electronic component, bonded to the second non-stretchable zone of the stretchable electronic component layer, wherein the flexible electronic component has a first perforation, and the first perforation is located outside the second non-stretchable zone of the stretchable electronic component layer; and
a protective layer, disposed on the carrier board layer and covering the stretchable electronic component layer and a part of the flexible electronic component, wherein the protective layer is located between the decorative component layer and the stretchable electronic component layer and between the decorative component layer and the flexible electronic component;
wherein a part of the protective layer is filled in the first perforation of the flexible electronic component and is connected to the carrier board layer.

13. The electronic device according to claim 12, further comprising:
a lower hard board layer, wherein the carrier board layer is located between the stretchable electronic component layer and the lower hard board layer, and the lower hard board layer overlaps with the second non-stretchable zone of the stretchable electronic component layer;
wherein the first perforation of the flexible electronic component overlaps with at least one of the upper hard board layer and the lower hard board layer.

14. The electronic device according to claim 1, further comprising:
a carrier board layer, wherein the stretchable electronic component layer is disposed on the carrier board layer, and the stretchable electronic component layer is located between the decorative component layer and the carrier board layer; and
a flexible electronic component, bonded to the second non-stretchable zone of the stretchable electronic component layer, wherein the flexible electronic component has a second perforation, the second non-stretchable zone of the stretchable electronic component layer has a second non-stretchable zone perforation, and the second perforation of the flexible electronic component is disposed corresponding to the second non-stretchable zone perforation of the stretchable electronic component layer; and
a protective layer, disposed on the carrier board layer and covering the stretchable electronic component layer and a part of the flexible electronic component, wherein the protective layer is located between the decorative component layer and the stretchable electronic component layer and between the decorative component layer and the flexible electronic component;
wherein a part of the protective layer is filled in the second perforation of the flexible electronic component and the second non-stretchable zone perforation of the stretchable electronic component layer and is connected to the carrier board layer.

15. The electronic device according to claim 14, further comprising:
a lower hard board layer, wherein the carrier board layer is located between the stretchable electronic component layer and the lower hard board layer, and the lower hard board layer overlaps with the second non-stretchable zone of the stretchable electronic component layer;
wherein the second perforation of the flexible electronic component and the second non-stretchable zone perforation of the stretchable electronic component layer overlap with the upper hard board layer and the lower hard board layer.

16. An electronic device, comprising:
a stretchable electronic component layer, having a stretchable zone, a first non-stretchable zone, and a second non-stretchable zone, wherein the stretchable zone is located between the first non-stretchable zone and the second non-stretchable zone;
a decorative component layer, disposed on the stretchable electronic component layer;
an upper hard board layer, embedded or buried in the decorative component layer and overlapping with the second non-stretchable zone of the stretchable electronic component layer;
a carrier board layer, wherein the stretchable electronic component layer is disposed on the carrier board layer, and the stretchable electronic component layer is located between the decorative component layer and the carrier board layer; and
a lower hard board layer, wherein the carrier board layer is located between the stretchable electronic component layer and the lower hard board layer, and the lower hard board layer overlaps with the second non-stretchable zone of the stretchable electronic component layer.
